(19) United States
(12) Patent Application Publication
(10) Pub. No.: US 2006/0244156 A1
(43) Pub. Date: Nov. 2, 2006

(54) Bond pad structures and semiconductor devices using the same

(76) Inventors: Tao Cheng, Hsinchu City (TW); Chao-Chun Tu, Hsinchu City (TW); Min-Chieh Lin, Chubei City (TW); C.C. Mao, Hsinchu City (TW); Hsiu Chen Peng, Hsinchu City (TW); D. S. Chou, Tuchen City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/108,407

(22) Filed: Apr. 18, 2005

(51) Int. Cl. H01L 23/52

(52) U.S. Cl. 257/784

(57) ABSTRACT

Bond pad structures and semiconductor devices using the same. An exemplary semiconductor device comprises a substrate. An intermediate structure is formed over the substrate. A bond pad structure is formed over the intermediate structure. In one exemplary embodiment, the intermediate structure comprises a first metal layer neighboring and supporting the bond pad structure and a plurality of second metal layers underlying the intermediate structure, wherein one of the second metal layers functions as a power line.

### BACKGROUND

The present invention relates to semiconductor devices, and more particularly to bond pad structures formed over a circuit region.

Performance characteristics of semiconductor devices are typically improved by reducing device dimensions, resulting in increased device densities and increased device packaging densities. This increase in device density places increased requirements on the interconnection of semiconductor devices, which are addressed by the packaging of semiconductor devices. One of the key considerations in the package design is the accessibility of the semiconductor device or the Input/Output (I/O) capability of the package after one or more devices have been mounted in the package.

In a typical semiconductor device package, the semiconductor die can be mounted or positioned in the package and can further be connected to interconnect lines of the substrate by bond wires or solder bumps. For this purpose the semiconductor die is provided with bond pads that are typically mounted around the periphery of the die and not formed over regions containing active or passive devices. FIG. 1 is schematic plan view showing a conventional layout of bond pads over a semiconductor die. In FIG. 1, a semiconductor die 10 is provided with a first region 12 in which active and/or passive devices (not shown) are formed. The first region 12 is separated from a second region 14, over which bond pads 16 are formed.

One reason the bond pads 16 are not formed over the first region 12 is related to the thermal and/or mechanical stresses that occur during the conductive bonding process. During conductive bonding, wires or bumps are connected from the bond pads to a supporting circuit board or to other means of interconnections.

Therefore, materials for intermetal dielectrics (not shown) incorporated in a interconnect structure of the semiconductor die 10, typically adjacent to and/or underlying the bond pads 16, are susceptible to damage during the conductive bonding due to insufficient mechanical strength against the bonding stresses. Thus, direct damage to the active or passive devices underlying the intermetal dielectric layers can be avoided since bond pads are provided around the periphery of the die. In such a design, however, overall die size cannot be significantly reduced since the bond pads 16 occupy a large portion of the top surface of the semiconductor die 10, causing extra manufacturing cost.

### SUMMARY

Bond pad structures and semiconductor devices using the same are provided. An exemplary embodiment of a semiconductor device comprises a substrate. An intermediate structure is disposed over the substrate. A bond pad structure is disposed over the intermediate structure. The intermediate structure comprises a first metal layer neighboring and supporting the bond pad structure and a plurality of second metal layers underlying the intermediate structure, wherein one of the second metal layers functions as a power line.

An exemplary embodiment of a bond pad structure, capable of distributing power, comprises a first dielectric layer having a power line therein. A second dielectric layer having a hollow metal portion therein overlies the first dielectric layer. A third dielectric layer having a bond pad overlies the second dielectric layer, wherein the bond pad overlies the hollow metal portion and the power line, and are electrically connected therewith.

A detailed description is given in the following embodiments with reference to the accompanying drawings.

### BRIEF DESCRIPTION OF THE DRAWINGS

The invention can be more fully understood by reading the subsequent detailed description and examples with reference made to the accompanying drawings, wherein:

FIG. 1 is a plan view showing a conventional layout of bond pads over a semiconductor die;

FIG. 2 is a plan view showing a bond pad layout over a semiconductor device, according to an embodiment of the invention;

FIG. 3 is a cross section taken along line 3-3 in FIG. 2, showing a structure of the semiconductor device;

FIGS. 4-5 are perspective plan views showing various layouts of a region 230 in FIG. 3;

FIG. 6 is a cross section of an exemplary embodiment of a semiconductor device, having a bond pad structure capable of distributing power;

FIG. 7 is a cross section of another exemplary embodiment of a semiconductor device, having a bond pad structure overlies interconnect lines only.

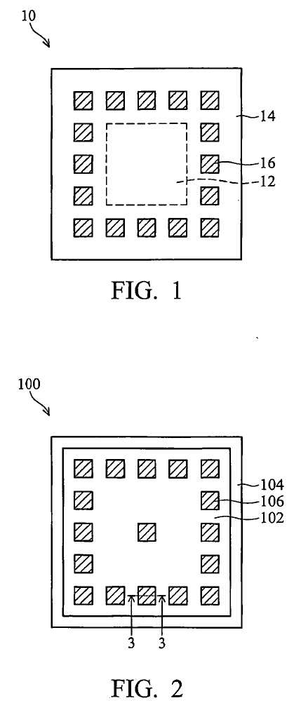

### DESCRIPTION

Bond pad structures and semiconductor devices using the same will now be described in detail. Such exemplary embodiments as will be described, can potentially reduce overall semiconductor die size. In some embodiments, this can be accomplished by forming bond pads over a circuit region with underlying electrical devices and interconnecting lines.

In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more laminated layers. The use of the term “low dielectric constant” or “low k” herein means a dielectric constant (k value) that is less than the dielectric constant of a conventional silicon oxide. Preferably, the low k dielectric constant is less than about 4.

FIG. 2 is a schematic plan view of an exemplary embodiment of a semiconductor die 100. The semiconductor die 100 is provided with a circuit region 102 surrounded by a peripheral region 104, which could be a guard ring region. The peripheral region 104 may protect the circuit region 102 from damage due to die separation. As shown in FIG. 2, bond pads 106 are formed on the periphery and/or center of the circuit region 102. Layouts of the bond pads 106 over the semiconductor die 100 are not limited to those illustrated in FIG. 2 and can be modified by those skilled in the art.

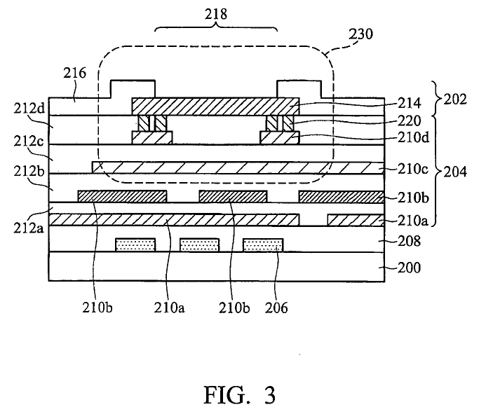

FIG. 3 is a cross section along line 3-3 in FIG. 2, showing a semiconductor device having a bond pad structure 202 formed over a substrate 200. In FIG. 3, the substrate 200 is provided with devices 206 thereon. The devices 206 can be active devices such as metal-oxide semiconductor (MOS) transistors, or passive devices such as capacitors, inductors, and resistors. These devices 206 are not limited to being formed on the substrate 200 and some of these devices 206 can be formed in the substrate 200 to thereby enhance die size reduction. Devices 206 can be formed by well known fabrication methods and as such will not be described here.

Dielectric layer 208 is provided over/between the devices 206 and an intermediate structure 204 is provided on the dielectric layer 208. The dielectric layer 208 provides insulation between the devices 206. The intermediate structure 204 comprises a plurality of metal layers 210a, 210b, 210c, and 210d respectively formed within dielectric layers 212a, 212b, 212c, and 212d, thereby functioning as an interconnect structure for electrically connecting the underlying devices 206 and the overlying bond pad structure 202. In some cases, the intermediate structure 204 electrically connecting the overlying bond pad structure 202 may electrically connect the electric device at any region within the semiconductor die. Connection therebetween can be achieved by forming conductive contacts (not shown) in the dielectric layer 208 at a position relative to the device 206 and is well-known by those skilled in the art.

The metal layers 210a-d can be substantially arranged along the x or y direction shown in FIG. 2 and are electrically connected by conductive vias (not shown) properly formed in the dielectric layers 212a-d. The conductive layers 210a-d can function as routing, signal or power lines along or in combination. Fabrication of such an intermediate structure 204 can be achieved by well-known interconnect fabrications, such as single/dual damascene process or other known line fabricating techniques. The metal layers 210a-d can comprise, for example, copper, aluminum, or alloys thereof. The dielectric layers 212a-d can comprise, for example, doped or undoped oxide or commercially available low k dielectrics and can be formed by, for example, plasma enhanced chemical vapor deposition (PECVD).

Still referring to FIG. 3, the bond pad structure 202 formed over the topmost dielectric layer 212d of the intermediate structure 204 includes a metal pad 214 partially covered by a passivation layer 216 and an exposed bonding region 218 for sequential conductive bonding. Metal pad 214 and the passivation layer 216 can be formed by well-known pad fabrications and will not be described here. The metal pad 214 can be, for example, a pad comprising aluminum, copper, or alloys thereof. The passivation layer 216 can comprise, for example, silicon nitride or silicon oxide and preferably comprises silicon nitride.

As shown in FIG. 3, the metal pad 214 is formed above a circuit region having underlying interconnecting lines (referring to metal layers 210a-d) and devices 206. Thus, the topmost metal layer 210d of the intermediate structure 204 can from with metal patterns insulated from the underlying metal layers 210a-c. The metal layers 210d can provide mechanical support to the overlying metal pad 214 and sustain stresses caused in sequential bonding processes. For this purpose, additional conductive vias 220 are required and provided in the portion of the dielectric layer 212d between the metal pad 214 and the underlying metal layer 210d to thereby enhance upward mechanical support.

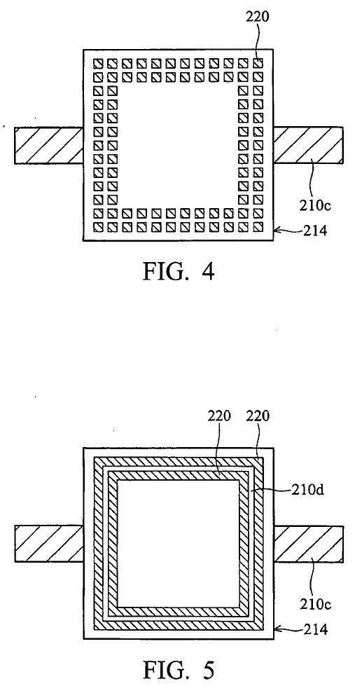

FIGS. 4-5 are perspective plan views showing configuration within a region 230 in FIG. 3. As shown in FIG. 4, the conductive vias 220 are formed as a plurality of conductive plugs surrounding a periphery of the metal pad 214. These conductive vias 220 in FIG. 4 are arranged in an orderly manner, for example, two by two along the periphery of the metal pad 214 and are electrically insulated from each other by the dielectric layer 212d (not shown). One of the underlying metal layers 210a-c of the intermediate structure 204, for example the metal layer 210c, can be disposed underneath the metal pad 214 to thereby enhance integrity of a semiconductor device and achieve maximum integrity when the metal layer 210c functions as a power line. In FIG. 5, a varied layout of the conductive vias 220 which are formed as two individual continuous conductive trenches within the dielectric layer 210d is shown. The conductive trenches annularly surround the periphery of the metal pad 214 and one of the underlying metal layers 210a-c of the intermediate structure 204, for example the metal layer 210c, can be disposed underneath the metal pad 214 to enhance integrity of a semiconductor device and achieve a maximum integrity when the metal layer 210c functions as a power line.

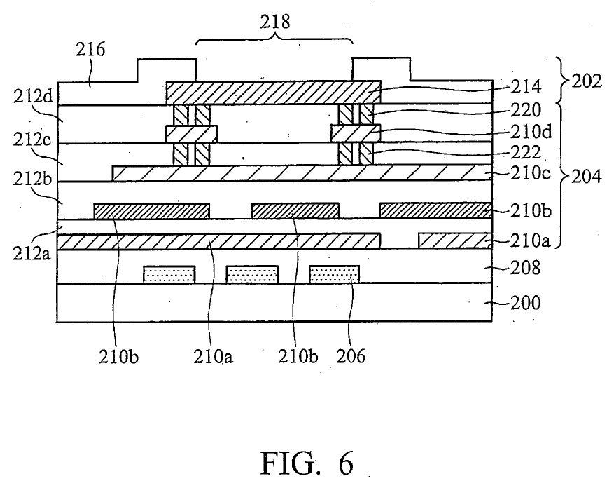

FIG. 6 shows a cross section of another exemplary embodiment of a semiconductor device with a bonding pad structure, in which like numbers from the described exemplary embodiment are utilized where appropriate. In this embodiment, the bond pad structure is illustrated as a bond pad for power distributing. As shown in FIG. 6, the bond pad structure 202 formed on the topmost dielectric layer 212d of the intermediate structure 204 has a metal pad 214 partially covered by a passivation layer 216 and exposes a bonding region 218 for sequential conductive bonding. Metal pad 214 and the topmost passivation layer 216 can be formed by well known pad fabrication and will not be described here. The metal pad 214 can be, for example, a pad comprising aluminum, copper, or alloys thereof. The passivation layer 216 may comprise, for example, silicon nitride or silicon oxide and preferably comprises silicon nitride.

As shown in FIG. 6, the metal pad 214 is now formed above a circuit region having underlying interconnecting lines (referring to metal layers 210a-d) and devices 206. In this embodiment, the upmost metal layer 210d of the intermediate structure 204 can be formed with metal patterns not only to provide mechanical support to the overlying metal pad 214 for sustaining stresses caused in sequential bonding processes but also to electrically connect the underlying metal layer 210c within the dielectric layer 210c. In this situation, additional conductive vias 220 and 222 are required and respectively provided in the dielectric layer 212d between the metal pad 214 and the underlying metal layer 210d and in the dielectric layer 212c between the metal layer 210d and the metal layer 210c thereunder. The metal layer 210c of the intermediate structure 204 is now underneath the metal pad 214 to enhance integrity of a semiconductor device and achieves maximum integrity when the metal layer 210c functions as a power line. Therefore, a power input (not shown) can directly pass through a conductive bonding sequentially formed within the bonding region 218 and arrive at certain underlying devices 206 through the intermediate structure 204. The metal pad 214 capable of distributing power can thus function as a power pad.

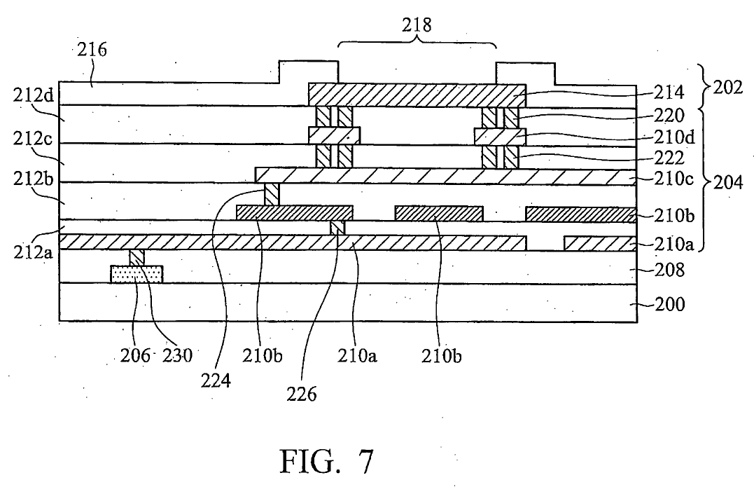

FIG. 7 is a cross section of another exemplary embodiment of a semiconductor device, with a bonding pad structure overlies interconnect lines only, in which like numbers from the described exemplary embodiments are utilized where appropriate. In this embodiment, the bond pad structure is also illustrated as a bond pad for power distributing.

In FIG. 7, the bonding region 218 only overlies the underlying intermediate structure 204 and no device 206 is formed thereunder. A device 206 can be formed under a region other than the bonding region 218 and electrically connect the overlying intermediate structure 204 and bond pad structure 202 through a conductive contact 230 and conductive vias 220, 222, 224, 226, respectively, as shown in FIG. 7.

Interconnections between the bond pad structure 202, the intermediate structure 204, and the devices 206 are not limited by that illustrated in FIGS. 3, 6, and 7. Those skilled in the art can properly modify interconnections therebetween according to real practices.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
an intermediate structure over the substrate; and
a bond pad structure over the intermediate structure, wherein the intermediate structure comprises:
a first metal layer neighboring and supporting the bond pad structure; and
a plurality of second metal layers underlying the intermediate structure, wherein one of the second metal layers functions as a power line.

2. The semiconductor device as claimed in claim 1, wherein the second metal layers are electrically insulated from the first metal layer.

3. The semiconductor device as claimed in claim 1, wherein the first metal layer is a hollow layer with a central dielectric portion and covered by the bond pad structure.

4. The semiconductor device as claimed in claim 1, further comprising a plurality of conductive vias between the first metal layer and the bond pad structure, forming electrical connections therebetween.

5. The semiconductor device as claimed in claim 1, wherein the first metal layer is formed within a PE oxide layer.

6. The semiconductor device as claimed in claim 1, further comprising at least one device formed within or over the substrate and the intermediate structure, wherein the device underlies the bond pad structure.

7. The semiconductor device as claimed in claim 6, wherein the device is a transistor, capacitor, inductor, or resistor.

8. The semiconductor device as claimed in claim 1, wherein the first metal layer comprises aluminum, copper or alloys thereof.

9. The semiconductor device as claimed in claim 1, wherein the second metal layer comprises aluminum, copper or alloys thereof.

10. The semiconductor device as claimed in claim 1, wherein the bond pad structure comprises aluminum, copper or alloys thereof.

11. The semiconductor device as claimed in claim 4, wherein the vias are formed as a continuous trench surrounding the bond pad structure.

12. The semiconductor device as claimed in claim 4, wherein the vias are formed as a plurality of electrically insulated plugs surrounding the bond pad structure.

13. A bond pad structure, capable of distributing power, comprising:
a first dielectric layer having a power line therein;
a second dielectric layer having a hollow metal portion therein, overlying the first dielectric layer; and
a third dielectric layer having a bond pad, overlying the second dielectric layer, wherein the bond pad overlies the hollow metal portion and the power line, and are electrically connected therewith.

14. The bond pad structure as claimed in claim 13, wherein the bond pad, the hollow metal portion, and the power line are electrically connected by a plurality of conductive vias respectively formed in the first and second dielectric layers.

15. The bond pad structure as claimed in claim 13, wherein the power line is underneath the bond pad.

16. The bond pad structure as claimed in claim 12, wherein the third dielectric layer comprises silicon nitride.

17. The bond pad structure as claimed in claim 13, wherein the second dielectric layer comprises PE oxide.

18. The bond pad structure as claimed in claim 13, wherein the hollow metal portion comprises aluminum, copper or alloys thereof.

19. The bond pad structure as claimed in claim 13, wherein the bond pad comprises aluminum, copper or alloys thereof.

20. A semiconductor device, comprising:
a substrate;
a plurality of first dielectric layers overlying the substrate, wherein the first dielectric layers are interleaved with a plurality of first metal layers and one of the first metal layers functions as a power line;
a second dielectric layer overlying the first dielectric layers, having a plurality of metal plugs therein; and
a metal pad overlying the second dielectric layer and supported by the metal plugs, wherein the metal plugs are arranged along a periphery of the metal pad.

21. The semiconductor device as claimed in claim 20, wherein the metal plugs are electrically insulated from each other.

22. The semiconductor device as claimed in claim 20, wherein the metal plugs are formed within a continuous trench in the second dielectric layer and the continuous trench is formed along a periphery of the metal pad.

23. The semiconductor device as claimed in claim 20, further comprising at least one device formed on the substrate, wherein the metal pad overlies the device.

24. The semiconductor device as claimed in claim 23, wherein the first metal layers electrically interconnect the device and the metal pad.

25. The semiconductor device as claimed in claim 23, wherein the device is a transistor, capacitor, inductor, or resistor.
